(19) United States
(12) Patent Application Publication
(10) Pub. No.: US 2010/0251536 A1
(43) Pub. Date: Oct. 7, 2010

(54) Heat-dissipating structure on case of industrial computer and manufacturing method thereof

(75) Inventor: Chien Shun Lin, Taipei (TW)

Correspondence Address: BACON & THOMAS, PLLC, 625 SLATERS LANE, FOURTH FLOOR, ALEXANDRIA, VA, 22314-1176, US

(73) Assignee: Moxa Inc., Taipei (TW)

(21) Appl. No.: 12/385,322

(22) Filed: Apr. 6, 2009

(51) Int. Cl. H05K 7/20; G06F 1/20; B23P 17/04

(52) U.S. Cl. 29/527.4; 361/679.54

(57) ABSTRACT

A heat-dissipating structure on the case of an industrial computer and the method of manufacturing the same are provided. Heat-conducting elements are connected to the computer case by low-temperature soldering to reduce the use of heat-dissipating elements. This method also effectively reduces thermal resistance and production cost. Therefore, the structure achieves the goals of reducing heat dissipation resistance and production cost.

### BACKGROUND OF THE INVENTION

1. Field of Invention

The invention relates to a computer case heat-dissipating structure and, in particular, to a computer case heat-dissipating structure with heat-conducting elements integrally soldered on the case. The invention also relates to the method of manufacturing the same.

2. Related Art

Thanks to the advances in technology, electronic devices have much better performance than before. However, these electronic devices produce heat during their operations. If such heat is not dissipated appropriately, their performance will reduce or the electronic devices may even bum down. Therefore, heat-dissipating structures have become indispensable in modern electronic devices.

Traditional heat-dissipating structures are designed for individual heat-generating elements. For those operating at low working frequencies, the heat can be easily dissipated using heat-dissipating fins. Please refer to FIG. 1, which is the side view of a conventional heat-dissipating structure. As shown in the drawing, several heat-dissipating fins 63 of high coefficient of thermal conductivity are attached on the heat-generating element 62 on the printed circuit board (PCB) 61. The heat-dissipating fins 63 absorb the heat generated by the heat-generating element 62 by thermal conduction. They then dissipate the heat through the larger contact area of the heat-dissipating fins 63 with cold air and natural convection. Therefore, heat can be efficiently removed.

However, most of modern electronic products are designed to be smaller, have more functions, and run at higher frequencies. In particular, industrial computers are more compact than office or home computers due to their working environment.

It is therefore necessary to improve the above-mentioned heat-dissipating structure to suit the requirement of compactness. Please refer to FIGS. 2A and 2B. FIG. 2A is a three-dimensional exploded view of the heat-dissipating structure of a conventional industrial computer. FIG. 2B is a schematic side view of the heat-dissipating structure of a conventional industrial computer.

Inside the computer case 71, there is at least one circuit board 72 equipped with at least one heat-generating element 721. Each of the heat-generating elements 721 is provided with a first heat-conducting pad 731, on which a corresponding heat-conducting element 74 is disposed. The conducting element 74 is fixed on the corresponding circuit board 72 using a fixing element 75. The conducting element 74 is further provided with a second heat-conducting pad 732, which is then attached onto the case 71. The heat produced by the heat-generating elements 721 is then conducted to the case 71 and dissipated to the environment there.

It is clear from FIG. 2B that the heat-dissipating structure in the prior art requires the heat produced by the heat-generating element 721 to go through the first heat-conducting pad 731, the heat-conducting element 74, and the second heat-conducting pad 732 before the removal. Different elements on the heat flow path have certain thermal resistance that causes difficulty in heat conduction. Moreover, the production cost is larger because more elements are involved. All these are shortcomings of the conventional heat-dissipating structures.

In summary, the prior art always has the problems of larger thermal resistance due to too many heat-conducting elements and of higher production costs. It is therefore necessary to provide a satisfactory solution.

### SUMMARY OF THE INVENTION

In view of the foregoing, the disclosed heat-dissipating structure on the case of an industrial computer includes at least one heat-conducting element and a case. The first heat-conducting surface and the second heat-conducting surface of each heat-conducting element are coated with a heat-conducting layer by electroplating. Various circuit boards are disposed inside the case. At least one inner surface of the case is coated with a second heat-conducting layer by electroplating. At least one soldering area of the second heat-conducting layer is applied with a low-temperature solder paste, forming a solder paste layer. Each of the heat-conducting elements is soldered to the soldering area by low-temperature soldering. The first heat-conducting layer and the second heat-conducting layer are connected and integrated into one heat-conducting sheet through the solder paste. The heat-conducting elements and the case are thus integrally connected.

The above-mentioned low-temperature soldering process involves the following steps. First, a pressure is imposed on each of the heat-conducting elements so that the first heat-conducting layer on the first heat-conducting surface thereof attaches onto the solder paste layer of the corresponding soldering area. The solder paste layer is then heated at a low temperature, so that the contact surfaces of the solder paste layer and the first and second heat-conducting layers become liquid. Finally, the system is cooled so that the first and second heat-conducting layers and the solder paste layer are connected together. Therefore, the heat-conducting elements are soldered to the soldering area. The first and second heat-conducting layers are integrated into one heat-conducting sheet, and the heat-conducting elements and the case are connected integrally.

The disclosed method of manufacturing the heat-dissipating structure on the case of an industrial computer includes the following steps. First, a first heat-conducting layer is coated on a first heat-conducting surface and a second heat-conducting surface of at least one heat-conducting element by electroplating. Afterwards, at least one inner surface of the case is coated with a second heat-conducting layer by electroplating. Afterwards, a low-temperature solder paste is applied on at least one soldering area of the second heat-conducting layer, forming a solder paste layer. Afterwards, each of the heat-conducting elements is imposed with a pressure so that the first heat-conducting layer on the first heat-conducting surface thereof attaches onto the solder paste layer of the corresponding soldering area. The solder paste layer is then heated at a low temperature, so that the contact surfaces of the solder paste layer and the first and second heat-conducting layers become liquid. Finally, the system is cooled so that the first and second heat-conducting layers and the solder paste layer are connected together. Therefore, the heat-conducting elements are soldered to the soldering area. The first and second heat-conducting layers are integrated into one heat-conducting sheet, and the heat-conducting elements and the case are connected integrally.

As described above, the invention differs from the prior art in that the heat-conducting elements and the case are coated with a heat-conducting sheet by electroplating. The heat-conducting elements are fixed on the case by low-temperature soldering. This reduces the use of heat-conducting elements and thus the thermal resistance and production cost.

In summary, the invention can effectively reduce the thermal resistance in heat dissipation and the production cost.

### BRIEF DESCRIPTION OF THE DRAWINGS

The invention will become more fully understood from the detailed description given herein below illustration only, and thus is not limitative of the present invention, and wherein:

FIG. 1 is a side view of a conventional heat-dissipating structure;

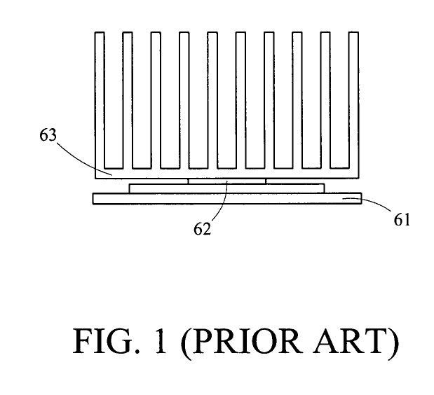

FIG. 2A is a three-dimensional view of a conventional heat-dissipating structure for an industrial computer;

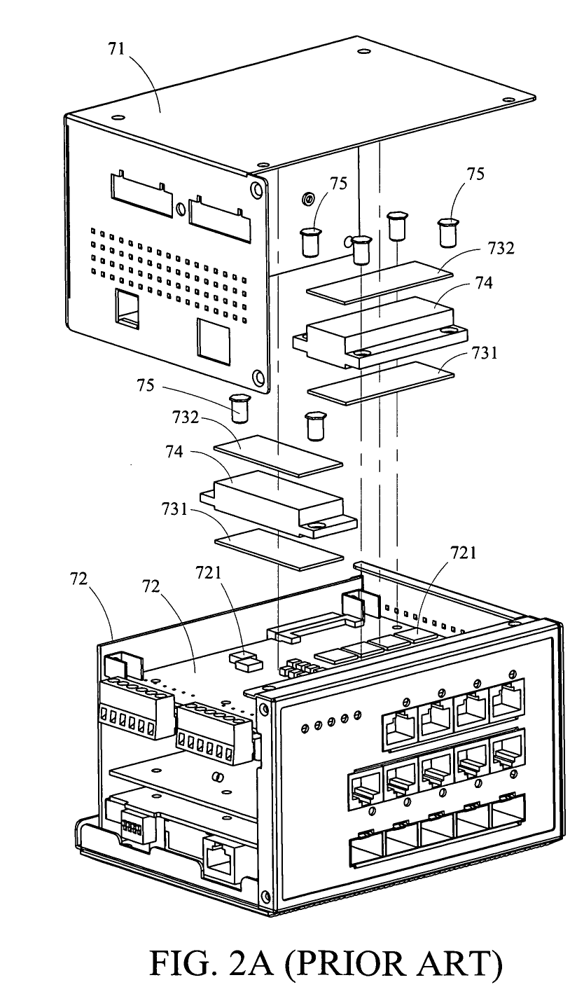

FIG. 2B is a side view of a conventional heat-dissipating structure for an industrial computer;

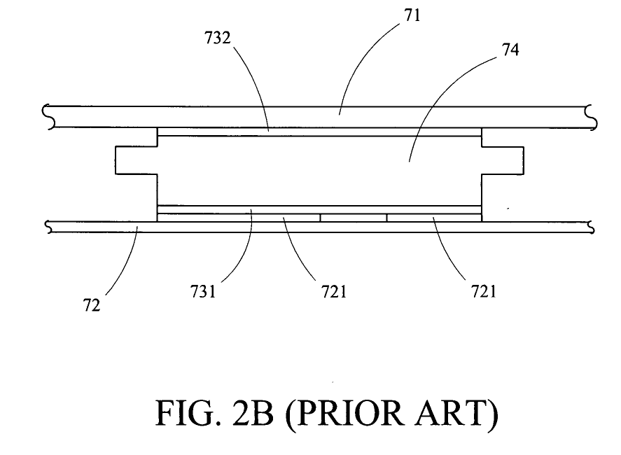

FIG. 3A is a three-dimensional view of the heat-dissipating structure according to the invention;

FIG. 3B is a schematic side view of the disclosed heat-conducting structure on the case of an industrial computer;

FIG. 3C is an enlarged view of the heat-conducting layer in the disclosed heat-conducting structure on the case of an industrial computer;

FIG. 3D is a three-dimensional view of the disclosed heat-dissipating structure on the case of an industrial computer; and

FIG. 4 is a three-dimensional view of the disclosed heat-dissipating structure.

### DETAILED DESCRIPTION OF THE INVENTION

The present invention will be apparent from the following detailed description, which proceeds with reference to the accompanying drawings, wherein the same references relate to the same elements.

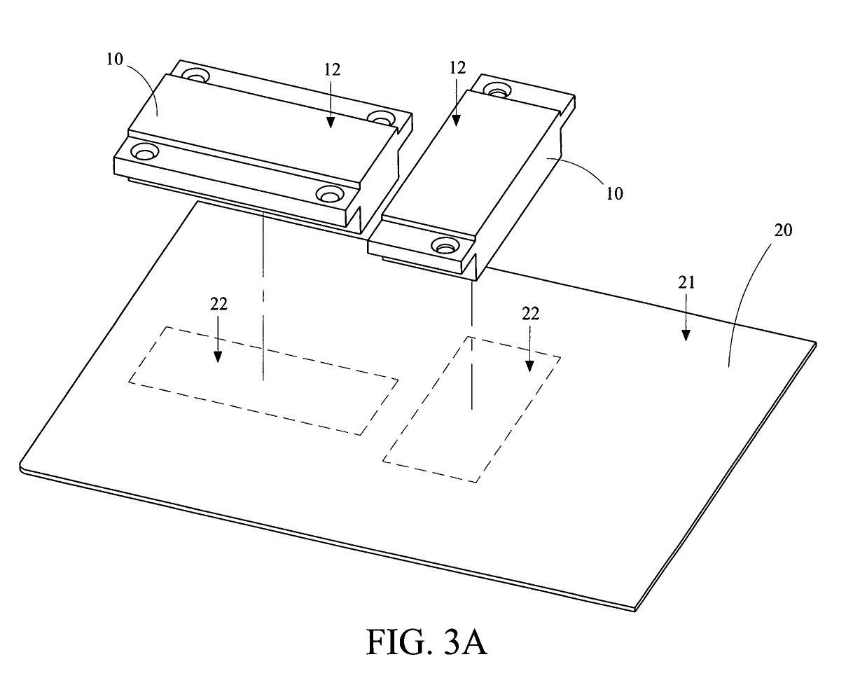

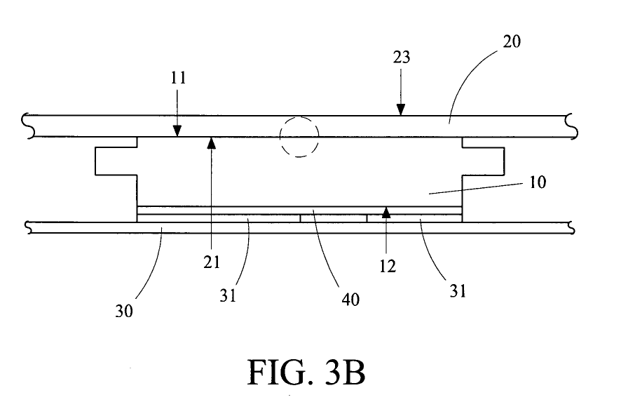

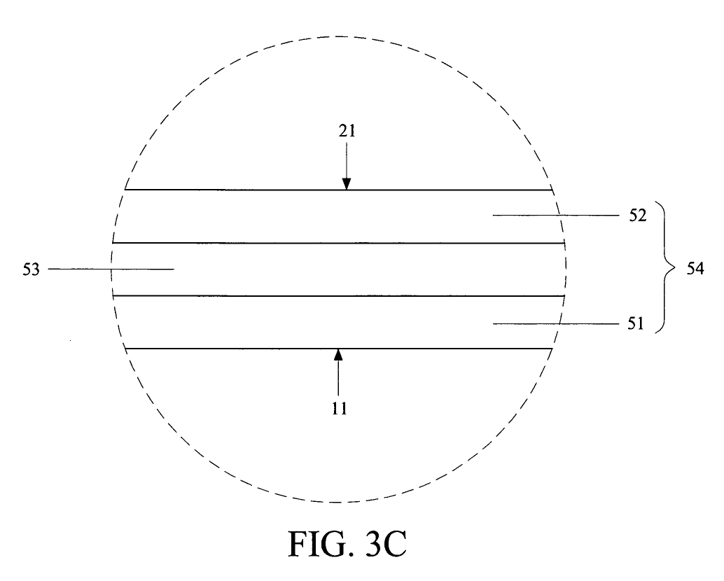

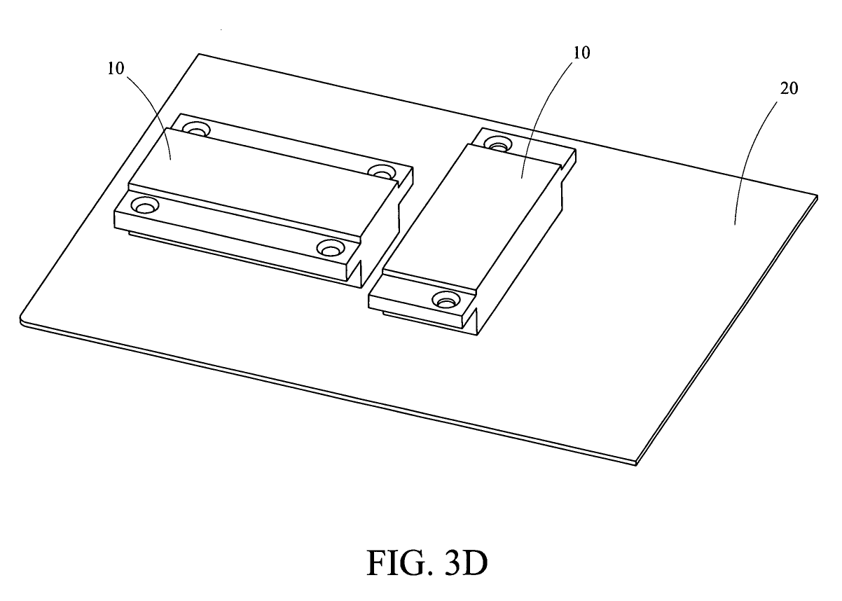

The manufacturing method of the heat-dissipating structure on the case of an industrial computer is first explained with reference to FIG. 3A. FIG. 3A is a three-dimensional view of the heat-dissipating structure according to the invention.

As shown in the drawing, the disclosed heat-dissipating structure on the case of an industrial computer consists of at least a heat-conducting element 10 and a case 20, which are integrally connected by soldering. The locations of the heat-conducting elements 10 on the case 20 are determined according to the locations of the heat-dissipating elements in the industrial computer.

Please refer to FIGS. 3B and 3C. FIG. 3B is a schematic side view of the disclosed heat-conducting structure on the case of an industrial computer. FIG. 3C is an enlarged view of the heat-conducting layer in the disclosed heat-conducting structure on the case of an industrial computer. Please also refer to FIG. 3A simultaneously in the following description.

As shown in FIG. 3B, a first heat-conducting layer 51 (see FIG. 3C) is coated on a first heat-conducting surface 11 and a second heat-conducting surface 12 of at least one heat-conducting element 10 by electroplating. The second heat-conducting surface 12 is on the back of the first heat-conducting surface 11. The first heat-conducting layer 51 is made of a metal of good thermal conductivity, such as copper, silver, nickel, etc. That is, the first heat-conducting layer 51 is formed on the first heat-conducting surface 11 and the second heat-conducting surface 12 of the heat-conducting element 10 by electroplating copper, silver, or nickel. These are only examples, and the invention is not limited to these cases.

At least one inner surface 21 of the case 20 is coated with a second heat-conducting layer 52 (see FIG. 3C) by electroplating. Only a single inner surface is shown in the drawing. But the invention is not limited to this example. The second heat-conducting layer 52 is made of a metal of good thermal conductivity, such as copper, silver, nickel, etc. That is, the second heat-conducting layer 52 is formed on the inner surface 21 of the case 20 by electroplating copper, silver, or nickel. These are only examples, and the invention is not limited to these cases.

After electroplating the first heat-conducting layer 51 on the first heat-conducting surface 11 and the second heat-conducting surface 12 on each of the heat-conducting elements 10 and the second heat-conducting layer 52 on each of the inner surfaces 21 (see FIG. 3A) of the case 20, the second heat-conducting layer 52 on each of the inner surfaces 21 of the case 20 is formed with at least one soldering area 22 (see FIG. 3A). Each of the soldering areas 22 corresponds to a heat-conducting element 31 on the circuit board 30. The soldering areas 22 are coated with low-temperature solder pastes to form a solder past sheet 53 (see FIG. 3C).

Afterwards, the second heat-conducting surface 12 of each of the heat-conducting elements 10 is imposed with a pressure, so that the first heat-conducting layer 51 on the first heat-conducting surface 11 of each of the heat-conducting elements 10 attaches onto the solder paste layer 53 on the soldering area 22 corresponding to the heat-conducting element 10.

Afterwards, each of the heat-conducting elements 10 and the case 20 is heated at a low-temperature (i.e., heating the solder paste layer 53). The contact surface 54 between the solder paste layer 53 and the first heat-conducting layer 51 and the contact surface 54 between the solder paste layer 53 and the second heat-conducting layer 52 is melted into liquid solder. For example, the low heating temperature is about 170 degrees Celsius. The heating time is about 30 minutes. The above-mentioned low-temperature heating temperature and heating time are only examples of the invention, and should not be used to restrict the scope of the invention.

Finally, each of the heat-conducting elements 10 and the case 20 stops the low-temperature heating and starts cooling. The first heat-conducting layer 51 and the second heat-conducting layer 52 are then connected via the solder paste layer 53. The heat-conducting elements 190 are then soldered on the corresponding soldering areas 22. The first heat-conducting layer 51 and the second heat-conducting layer 52 integrate into a heat-conducting sheet 54. The heat-conducting elements 10 and the case 20 are integrally connected. The result is shown in FIG. 3D, which shows a three-dimensional view of the disclosed heat-dissipating structure on the case of an industrial computer.

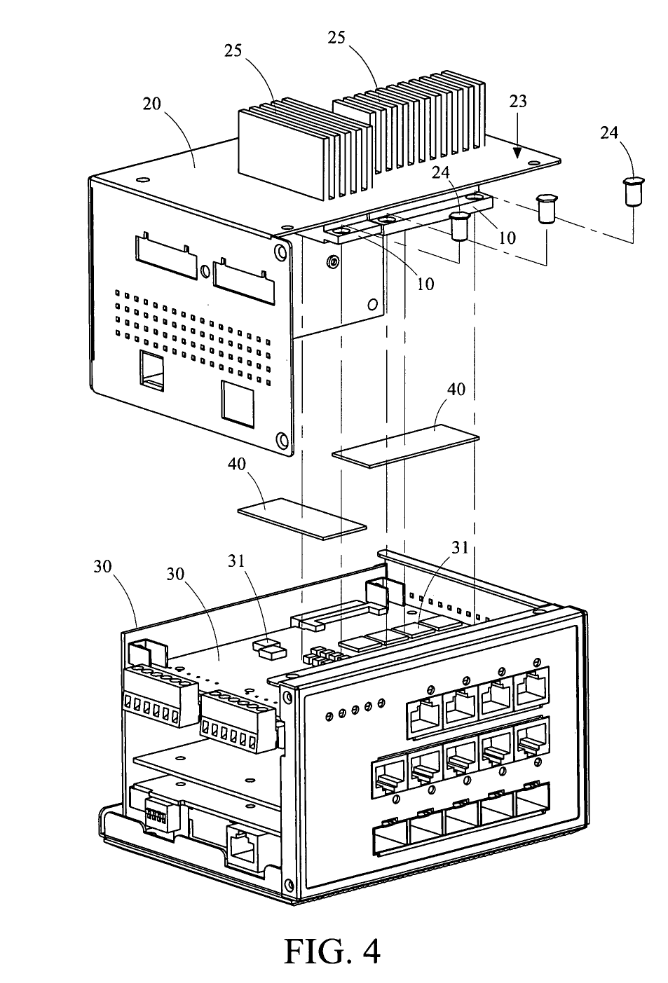

The disclosed method has been described above. The heat-dissipating structure on the case of an industrial computer is detailed below. Please refer to FIG. 4, which is a three-dimensional view of the disclosed heat-dissipating structure. As shown in the drawing, the heat-dissipating structure according to the invention includes: at least one heat-conducting element 10 and a case 20.

Using the above-mentioned manufacturing process, the heat-conducting elements 10 are soldered onto the case 20 so that they are integrally connected. The case 20 can further be provided with at least one circuit board 30 with at least one heat-generating element 31. The heat-conducting elements 10 correspond to heat-generating elements 31 on the circuit boards 30. Generally speaking, the heat-generating element is a chip with operating functions, such as a central processing unit (CPU). This is merely an example, and should not be used to restrict the scope of the invention.

Each of the heat-generating elements 31 on the circuit boards 30 can be further attached with at least one heat-conducting pad 40. The integrally connected heat-conducting elements 10 and case 20 can attach to the corresponding heat-conducting pads 40 through the second heat-conducting surfaces (not shown) of the heat-conducting elements 10. The heat-conducting elements 10 are thus fixed onto the corresponding circuit boards 30. Not only does this achieve the fixing effect, the heat-conducting elements 20, the heat-conducting pads 40, and the heat-generating elements 31 are more tightly connected for better heat conduction.

As shown in FIG. 4, the heat-conducting elements 20, the heat-conducting pads 40, and the heat-generating elements 31 are fixed on the circuit boards 30 via fixing elements 24. This drawing only illustrates one example, and should not be used to restrict the scope of the invention. Any means that fixes the heat-conducting elements 10 on the circuit boards 30 should be included in the invention.

As described above, the heat-generating elements 31 on the circuit boards 30 dissipate their heat via the corresponding heat-conducting pads 40 and the heat-conducting elements 10 attached thereon to the case 20. The heat is then removed from the case 20 into the environment.

The heat-conducting pad 40 is made of a mixture of a thermal plastic polymer and a semiconductor with good thermal conductivity. The case 20 and the heat-conducting elements 10 are made of materials with good thermal conductivity, such as aluminum, iron, etc. These are only examples, and should not be used to restrict the scope of the invention. As a result, the heat-conducting pads 40 attach to the corresponding heat-generating elements 31 and the heat-conducting elements 10 with good thermal conductivity.

It should be noted that the circuit boards 30 can achieve different functions as they have different normal and operational electronic elements in various combinations. Using circuit boards 10 with different functions in an industrial computer can extend the versatility thereof. Thus, the case 20 can be disposed with at least one circuit board 30. Through the heat-conducting elements 10 soldered on different inner surfaces 21 of the case 20, the heat produced by the heat-generating elements 31 on different circuit boards 30 inside the case 20 can be dissipated.

There can be several heat-dissipating fins 25 on the outer surfaces 23 of the case 20 to increase the heat-dissipating area and heat-dissipating efficiency thereof. In addition, to save material costs, some heat-dissipating fins can be directly disposed on the outer surface 23 of the case 20 that corresponds to the heat-conducting element 10. Besides saving the material cost, the heat-dissipating efficiency can be locally enhanced.

Although the case 20 can be prepared by aluminum extrusion Oust one example of the invention) so that the heat-conducting elements 10 and the case are integrally formed, this is not suitable for more complicated designs of circuits. The heat-conducting elements 10 and the case 20 will interfere in the production. The invention can effectively prevent such interference by fixing individual circuit boards on the corresponding soldering areas 22.

Moreover, the disclosed heat-dissipating structure can largely reduce the thermal resistance in the heat-conducting elements 10 and the case 20. The electroplating process performed on the heat-conducting elements 10 and the case 20 can prevent their surfaces from oxidation as well as enhance their strength and anti-erosion ability. At the same time, the invention reduces the use of heat-conducting pads 40 to save the cost.

In summary, the invention differs from the prior art in that the heat-conducting elements and the case are electroplated with a heat-conducting sheet. The heat-conducting elements are fixed on the case using low-temperature soldering. This reduces the use of heat-dissipating elements and thus the thermal resistance. So the invention can significantly improve heat dissipation and reduce the production cost.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A heat-dissipating structure on the case of an industrial computer, comprising:
at least one heat-conducting element, whose first heat-conducting surface and second heat-conducting surface are coated with a first heat-conducting layer by electroplating; and
a case, which accommodates a plurality of circuit boards and at least one inner surface of which is coated with a second heat-conducting layer by electroplating, at least one soldering area on the second heat-conducting layer being coated with a low-temperature solder paste to form a solder paste layer, the heat-conducting elements being soldered to the soldering areas by low-temperature soldering, and the first heat-conducting layer and the second heat-conducting layer being connected into a heat-conducting sheet through the solder paste layer, thereby integrally connecting the heat-conducting elements and the case.

2. The heat-dissipating structure on the case of an industrial computer according to claim 1, wherein the first heat-conducting layer and the second heat-conducting layer are made of metals of good thermal conductivity.

3. The heat-dissipating structure on the case of an industrial computer according to claim 1, wherein the electroplating process uses nickel.

4. The heat-dissipating structure on the case of an industrial computer according to claim 1, wherein the second heat-conducting surface on the back of the first heat-conducting surface.

5. The heat-dissipating structure on the case of an industrial computer according to claim 1, wherein the outer surface of the case is provided with a plurality of heat-dissipating fins.

6. The heat-dissipating structure on the case of an industrial computer according to claim 1, wherein the outer surface of the case corresponding to the soldering areas is provided with a plurality of heat-dissipating fins.

7. The heat-dissipating structure on the case of an industrial computer according to claim 1, wherein the case is made of a metal of good thermal conductivity.

8. The heat-dissipating structure on the case of an industrial computer according to claim 1, wherein the heat-conducting pad is made of a mixture of a soft thermal plastic polymer and a semiconductor of good thermal conductivity.

9. The heat-dissipating structure on the case of an industrial computer according to claim 1 further comprising at least one heat-conducting pad attaching to the first heat-conducting layer of the second heat-conducting surface.

10. The heat-dissipating structure on the case of an industrial computer according to claim 9 further comprising at least one circuit board with at least one heat-generating element and the heat-conducting pads attach to the heat-generating elements.

11. The heat-dissipating structure on the case of an industrial computer according to claim 1, wherein the heat-conducting elements are fixed on the corresponding circuit boards.

12. A manufacturing method for a heat-dissipating structure on the case of an industrial computer, comprising the steps of:
coating a first heat-conducting layer on a first heat-conducting surface and a second heat-conducting surface of at least one heat-conducting element by electroplating;
coating a second heat-conducting layer on at least one inner surface of a case by electroplating;
coating a low-temperature solder paste on at least one soldering area of the second heat-conducting layer to form a solder paste layer;
imposing a pressure on the heat-conducting elements so that the first heat-conducting layer on the first heat-conducting surface of the heat-conducting elements attaches onto the solder paste layer on the soldering areas corresponding to the heat-conducting elements; and
heating the solder paste layer at a low temperature so that the contact surfaces of the solder paste layer with the first and second heat-conducting layers melt into a liquid, and cooling the system so that the first and second heat-conducting layers are connected with the solder paste layer, thereby integrally connecting the heat-conducting elements and the case.

13. The manufacturing method of claim 12, wherein the step of coating a first heat-conducting layer on a first heat-conducting surface and a second heat-conducting surface of at least one heat-conducting element by electroplating uses nickel for coating.

14. The manufacturing method of claim 12 further comprising the step of disposing a plurality of heat-dissipating fins on the outer surface of the case.

15. The manufacturing method of claim 12 further comprising the step of disposing a plurality of heat-dissipating fins on the outer surface of the case corresponding to the soldering areas.

16. The manufacturing method of claim 12 further comprising the step of attaching at least one heat-conducting pad on the first heat-conducting layer of the second heat-conducting surface.

17. The manufacturing method of claim 16 further comprising the step of attaching the heat-conducting pads on at least a heat-generating element of at least one circuit board.

18. The manufacturing method of claim 12 further comprising the step of fixing the heat-conducting elements on the corresponding circuit boards.
